(19) United States
(12) Patent Application Publication
(10) Pub. No.: US 2025/0317135 A1
(43) Pub. Date: Oct. 9, 2025

(54) APPARATUS, CONTROL DEVICE AND METHOD FOR SWITCHING A SWITCHING ELEMENT

(71) Applicant: Fraunhofer-Gesellschaft zur Förderung der angewandten Forschung e.V., München (DE)

(72) Inventors: Nico SCHMIED, Erlangen (DE); Stefan MATLOK, Erlangen (DE)

(73) Assignee: Fraunhofer-Gesellschaft zur Förderung der angewandten Forschung e.V., München (DE)

(21) Appl. No.: 19/090,384

(22) Filed: Mar. 25, 2025

Related U.S. Application Data
(63) Continuation of application No. PCT/EP2023/076442, filed on Sep. 26, 2023.

(30) Foreign Application Priority Data
Sep. 26, 2022 (DE) 102022210134.0

(51) Int. Cl. H03K 17/0814; H02M 1/32; H02M 3/00; H02M 3/158

(52) U.S. Cl. CPC H03K 17/08142; H02M 1/32; H02M 3/01; H02M 3/158; H03K 2217/009

(57) ABSTRACT

An apparatus includes a switch arrangement comprising a switching element and a control device that is configured to switch the switching element on the basis of a turn-off current that is determined by the relationship that

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number; wherein at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

### CROSS-REFERENCE TO RELATED APPLICATIONS

This application is a continuation of copending International Application No. PCT/EP2023/076442, filed Sep. 26, 2023, which is incorporated herein by reference in its entirety, and additionally claims priority from German Application No. 102022210134.0, filed Sep. 26, 2022, which is also incorporated herein by reference in its entirety.

The present invention relates to an apparatus comprising a switch arrangement including a switching element, to a control device and to methods for switching a switching element. The present invention relates in particular to an extended zero overvoltage switching range (overvoltage-free switching).

### BACKGROUND OF THE INVENTION

In power electronics, there are countless topologies and circuits that switch a current path on and off with the help of a transistor or semiconductor switch. The current path to be switched consists of an electrical conductor and a conductor loop, which also forms a parasitic inductance due to natural laws. This inductance, typically in the range of 1 nH to 100 nH, prevents the switching operation from being able to proceed as quickly as desired. With increasingly faster switching operations in the range of 1 ns to 1000 ns (depending on the power class), high turn-off overvoltages arise at the switching element, in particular during turning off.

EP 3 512 085 A1 describes a concept for switching a semiconductor switch with low overvoltages.

Based on this, it would be desirable to enable a loss-free or low-loss switching also under other, additional conditions.

### SUMMARY

According to an embodiment, an apparatus may have: a switch arrangement including a switching element that is configured for turning off an electrical current path of a commutation circuit, wherein the commutation circuit includes a free-running element with a parallel-effective capacitance; a control device that is configured to control the switching element for turning off and for carrying out a switching operation; wherein the control device is configured to switch the switching element for the switching operation with a channel turn-off time duration that is shorter than a period duration of a resonance vibration of the commutation circuit, in order to excite a vibration in the commutation circuit; wherein the control device is configured for an operating state, in which the switching operation is carried out based on a turn-off current to be turned off, if it is satisfied within a tolerance range that:

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number;
wherein at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

According to another embodiment, a control device that is configured to switch a switching element for carrying out a turn-off operation may have: wherein the control device is configured to determine, based on a property of the switching element, a result that indicates a turn-off current that flows through the switching element for the turn-off operation, that satisfies the condition within a tolerance range that:

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and

at least one of the conditions is satisfied:

$$n = 2 i + 1 , i ∈ ; \qquad 1 )$$

$${C}_{eff 1} \neq {C}_{eff 2} for n = 2 i + 1 , i ∈ \qquad 2 )$$

and to switch the switching element based on the result.

According to another embodiment, a method for controlling an apparatus with a switch arrangement including a switching element that is configured for turning off an electrical current path of a commutation circuit, wherein the commutation circuit includes a free-running element with a parallel-effective capacitance; may have the step of: controlling the switching element for turning off and for carrying out a switching operation; so that, for the switching operation, the switching element is switched with a channel turn-off time duration that is shorter than a period duration of a resonance vibration of the commutation circuit, in order to excite a vibration in the commutation circuit; so that the switching operation is carried out based on the turn-off current to be turned off, if it is satisfied within a tolerance range that:

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number; and
so that at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

According to another embodiment, a method for controlling a switching element for carrying out a turn-off operation may have the step of: determining, based on a property of the switching element and for obtaining a result that indicates a turn-off current that flows through the switching element for the turn-off operation, that satisfies the condition within a tolerance range that:

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and

at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

Another embodiment may have a non-transitory digital storage medium having a computer program stored thereon to perform any of the inventive methods when said computer program is run by a computer.

A core idea of the present invention is the finding that a favorable turn-off current, which enables low-loss turning-off, can be determined depending on an intermediate circuit voltage and effective capacitances and inductances of the commutation resonant circuit, and for this purpose several valid values are present, which further enable, by a corresponding choice of the applicable value, adjustment of a power, for example, of a DC-DC converter or, conversely, determination of a corresponding turn-off current depending on a needed power of a DC-DC converter or the like.

According to an embodiment, an apparatus includes a switch arrangement comprising a switching element that is configured for turning off an electrical current path of a commutation circuit, wherein the commutation circuit comprises a free-running element with a parallel-effective capacitance. The apparatus includes a control device that is configured to control the switching element for turning off and for carrying out a switching operation. The control device is configured to switch the switching element for the switching operation with a channel turn-off time duration that is shorter than a period duration of a resonance vibration of the commutation circuit, in order to excite a vibration in the commutation circuit. The control device is configured for an operating state, in which the switching operation is carried out based on a turn-off current to be turned off, if it is satisfied within a tolerance range that

$${I}_{TO , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{TO,n} describes the turn-off current to be turned off by the switching element, V_{DC} describes an intermediate circuit voltage of the commutation circuit, C_{eff1} describes an effective, i.e. connected and/or parasitic, capacitance of the commutation resonant circuit associated with the switching element, C_{eff2} describes an effective capacitance of the commutation resonant circuit associated with the free-running element, Lp describes an effective electrical inductance of the commutation resonant circuit, and n describes a natural number;
wherein at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

With the parameter n, properties of a corresponding circuit can be adjusted for example, a power by the different amount of the turn-off current, or, conversely, based on requirements on the apparatus, the turn-off current can be adapted by a corresponding selection of the parameter. The consideration of different effective capacitances alternatively or additionally enables a precise adaptation to the actually present circuit to be carried out.

According to an embodiment, a control device is configured to switch a switching element for carrying out a turn-off operation. For this purpose, the control device is configured to determine, based on a property of the switching element, that a turn-off current, which flows through the switching element, satisfies the condition within a tolerance range that

$${I}_{TO , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and
at least one of the conditions is satisfied:

$$n = 2 i + 1 , i ∈ ; \qquad 1 )$$

$${C}_{eff 1} \neq {C}_{eff 2} for n = 2 i + 1 , i ∈ \qquad 2 )$$

and to switch the switching element based on the result.

According to an embodiment, a method for controlling an apparatus with a switch arrangement comprising a switching element that is configured for turning off an electrical current path of the commutation circuit, wherein the commutation circuit comprises a free-running element with a parallel-effective capacitance, comprises the following steps: controlling the switching element for turning off and for carrying out a switching operation. In this case, for the switching operation, the switching element is switched with a channel turn-off time duration that is shorter than a period duration of a resonance vibration of the commutation circuit, in order to excite a vibration in the commutation circuit, and the switching operation is carried out based on the turn-off current to be turned off, if it is satisfied within a tolerance range that

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number; and
such that at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

According to an embodiment, a method for controlling a switching element for carrying out a turn-off operation includes determining, based on a property of the switching element and for obtaining a result, that a turn-off current, which flows through the switching element, satisfies the condition within a tolerance range that

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and
at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

### BRIEF DESCRIPTION OF THE DRAWINGS

Embodiments of the present invention will be detailed subsequently referring to the appended drawings, in which:

FIG. 1 is a schematic block diagram of an apparatus according to an embodiment;

FIG. 2 is a schematic block diagram of the topology of the apparatus from FIG. 1 with emphasis on the active participants of a resonant circuit;

FIG. 3 are schematic diagrams for the discussion of known measures of additional switching currents in accordance with embodiments of the present invention;

FIGS. 4a-c are exemplary representations of voltages across an exemplary semiconductor switch of the apparatus of FIG. 1 in accordance with embodiments of the present invention;

FIG. 5 is a schematic representation of two curves of parameters of an apparatus in accordance with embodiments of the present invention; and

FIGS. 6a-b are exemplary temporal relationships of different parameters of embodiments described herein.

### DETAILED DESCRIPTION OF THE INVENTION

Before embodiments of the present invention are explained in detail below with reference to the drawings, it is pointed out that identical, functionally equal or equal elements, objects and/or structures in the different figures are provided with the same reference numbers, so that the description of these elements illustrated in different embodiments is interchangeable or interapplicable.

Embodiments described below are described in connection with a plurality of details. However, embodiments can also be implemented without these detailed features. Further, for the sake of clarity, embodiments are described using block diagrams as a replacement for a detailed representation. Further, details and/or features of individual embodiments can be readily combined with each other, as long as it is not explicitly described to the contrary.

The following embodiments relate to the switching, in particular the switching-off or turning-off, of a switching element. Some of the embodiments relate in particular to the use of a semiconductor switch as a switching element, wherein the embodiments are not limited thereto. As an alternative or in addition to a semiconductor switch, other switching elements can also be arranged, which are configured for changing between a conducting and a non-conducting state, for instance relays or MEMS relays, transistors, for instance based on carbon nanotubes (CNT) materials and/or diamond materials. Transistors can also be manufactured as MOSFET transistors or bipolar transistors and/or in a manufacturing technology other than MOS.

A possible field of application of such a switching element is a DC-DC converter, wherein current paths are also turned off in other environments using switching elements, for instance for the operation or deactivation of loads. DC-DC converters can be configured to convert DC voltage with a first electrical voltage level or potential to a second electrical voltage level or potential, wherein the second level can be larger or smaller than the first level. DC-DC converters can comprise a semiconductor switch that is switched by a control device.

The following embodiments relate to switching operations in semiconductor switches. In the context of the embodiments described herein, these are linked to commutation operations in commutation circuits, for example in connection with DC-DC converters. This means that the commutation operation can be triggered by the switching operation. In this respect, in the context of some of the embodiments described herein, it can be referred to synonymously that a switching operation excites an exciter resonant circuit of the commutation circuit and that a commutation operation initiated by the switching operation excites the exciter resonant circuit of the commutation circuit.

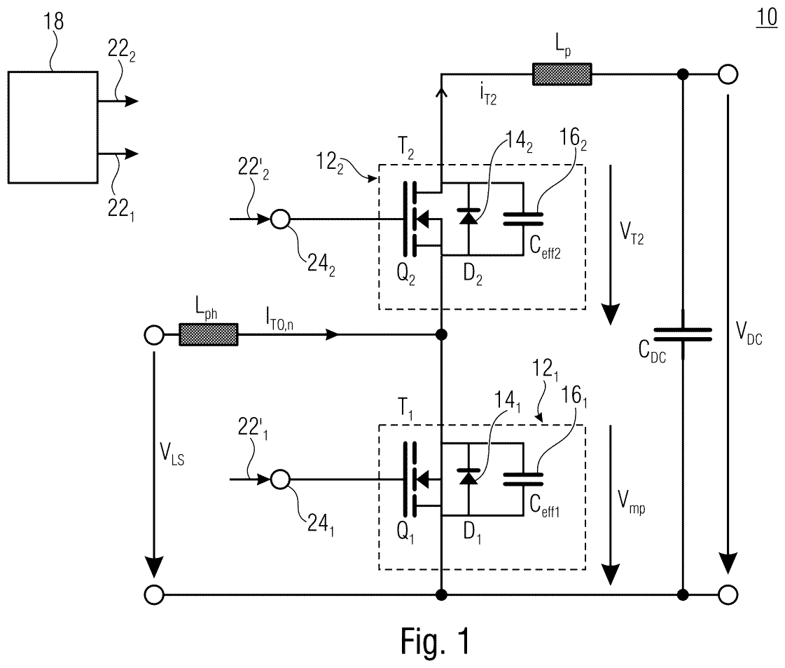

FIG. 1 shows a schematic block diagram of an apparatus 10 according to an embodiment. The apparatus 10 includes a switch arrangement 12 comprising at least one semiconductor switch 121. FIG. 1 shows an exemplary half-bridge topology of a DC-DC converter in which two semiconductor switches 12₁ and 12₂ are arranged merely for illustration purposes. These are formed by way of example as MOSFET transistors and possibly comprise intrinsic body diodes 14₁ and 14₂, respectively, which are designated as D₁ and D₂. However, it should be noted that, as an alternative to a body diode, a discrete free-running element can be connected or coupled both in the case of MOSFET transistors and in the case of other implementations. Further, FIG. 1 shows effective capacitances C_{eff1} and C_{eff2}, respectively, for the semiconductor switches 12₁ and 12₂, which can comprise, for example, parasitic capacitances of the transistors 12₁ and 12₂, but are not limited thereto. Thus, for example, additional capacitances can also be arranged, for instance by providing discrete devices, in order to adapt the effective capacitance.

Although FIG. 1 shows a half-bridge topology with two semiconductor switches 12₁ and 12₂, other topologies can comprise less than two semiconductor switches, i.e. one semiconductor switch, or more than two semiconductor switches, for example three, four or more. In principle, the topology can deviate from a half-bridge topology as desired.

The semiconductor switch 12₁ is configured for turning off an electrical current path of a commutation circuit. The commutation circuit includes a free-running element, for instance the diode 14₂, and a capacitance C_{eff2} and 16₂, respectively, that is effective in parallel with the free-running element. The free-running element can be associated with the semiconductor switch 12₂ or can be a discrete device. For another state of the circuit of FIG. 1, the roles of the semiconductor switches 12₁ and 12₂ can be interchanged and, for example, the semiconductor switch 12₂ can be switched, which results in a corresponding complementary change of the above-described mathematical relationship.

A control device 18 of the apparatus 10 is configured to control the semiconductor switch 12₁ and/or the semiconductor switch 12₂. For this purpose, the control device 18 can provide control signals 22₁ and 22₂, respectively, which are coupled directly or indirectly, for instance by interposing a driver or an amplifier, to control inputs 24₁ and 24₂, respectively, which are configured to receive a corresponding input signal 22′₁ and 22′₂, respectively, which can be based on the control signals 22₁ and 22₂, respectively, or can correspond thereto.

As will be explained in more detail below, the control device 18 is configured to switch the semiconductor switch 12₁ for the switching operation with a channel turn-off time duration that is shorter than a period duration of a resonance vibration of the commutation circuit. This enables a vibration in the commutation circuit to be excited. In this case, the control device 18 is configured for an operating state, in which the switching operation of the switch 12₁ is carried out based on a turn-off current to be turned off. For the turn-off current, it is satisfied within a tolerance range that

$${I}_{TO , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

In this case, ITO,n describes the turn-off current to be turned off by the semiconductor switch 12₁, VDC describes the intermediate circuit voltage of the commutation circuit, Ceff1 describes an effective, i.e. connected and/or parasitic, capacitance of the commutation resonant circuit associated with the semiconductor switch 12₁, Ceff2 describes an effective capacitance of the commutation resonant circuit associated with the free-running element, and Lp describes an effective electrical inductance of the commutation resonant circuit. n describes a natural number. In this case, at least one of the conditions is satisfied that n=2i+1, i∈ [symbol] . Alternatively or additionally, it is satisfied that C_{eff1}≠C_{eff2} für n=2i+1, i∈ [symbol] . In other words, the parameter n is a natural odd number>1 and/or the two capacitances differ from one another.

Each of the two conditions a) n>1 on the one hand and b) C_{eff1}≠C_{eff2} on the other hand can be implemented independently of one another and this enables corresponding advantages.

For increasing values of the parameter n, it can be obtained therefrom that the turn-off current decreases at the increasing commutation time duration t_{ZOS,n} associated with increasing values for n. When used in a DC-DC converter, this can result, for example, in a decreasing output power.

Further, FIG. 1 shows a switching arrangement possibly occurring in practice with an intermediate circuit capacitance C_{DC} and a phase inductance Lₚₕ. A switching cell includes, for example, the switching element 12₁ and 12₂ and the respective free-running element 14₁ and 14₂, respectively, as well as an effective commutation inductance Lp, which can include parasitic and/or discrete inductances. Further, the switching cell can include parallel capacitances C_{eff1} (16₁) and C_{eff2} (16₂) effective with respect to the switching elements 12₁, 12₂ and free-running elements 14₁, 14₂. The voltage vₘₚ designates the voltage dropping across the switched switching element 12₁. The voltages vₘₚ and v_{T2} illustrated in FIG. 1 relate to the voltages dropping across the switching elements 12₁ and 12₂, respectively, of which vₘₚ will be discussed in more detail in connection with FIG. 7b.

The voltages V_{DC} and V_{LS}, in connection with the switch control, result in a changing current flow in the phase inductance Lₚₕ. In the turn-off operation, the respective switching element, here the semiconductor switch 12₁, is thus needed to turn off a current I_{TO,n} (turn-off), the turn-off current, which corresponds to the instantaneous current flow through Lₚₕ. Due to the turn-off, the current path changes from the switching element to the free-running element. This change can be referred to as commutation operation. Embodiments described herein describe an advantageous method and corresponding apparatuses for implementing this commutation.

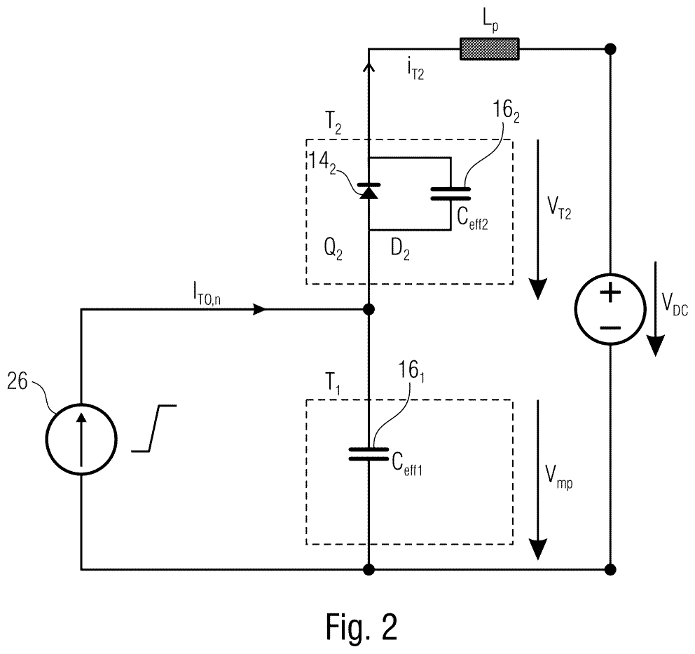

FIG. 2 shows a schematic block diagram of the topology of the apparatus 10 with emphasis on the active participants of the resonant circuit. FIG. 2 is valid, for example, for a state after turning-off the channel of the transistor T1, but during the commutation duration t_{ZOS,n}. For this purpose, the phase inductance Lₚₕ can be replaced by a current source 26. The resonant circuit or commutation circuit in this case includes the parasitic inductance Lₚ, the free-running element 14₂ as well as the capacitances 16₁ and 16₂ and C_{eff1} and C_{eff2}, respectively.

In other words, the resonant circuit, which includes the parasitic elements, is excited by a specific turn-off current, which will be discussed below. By way of example, a half-bridge topology is used with reference to FIGS. 1 and 2, but the described ZOS (zero overvoltage switching, overvoltage-free or-avoiding switching) according to the embodiments described herein can be used for a plurality of hard-switching topologies.

The resonant circuit includes, for example, the parasitic capacitances C_{eff1} and C_{eff2} of the two power semiconductors T₁ and T₂ as well as the parasitic inductance Lₚ. While in EP 3 512 085 A1, the resonant circuit is excited such that the commutation is concluded after half a period of the resonant frequency, embodiments described herein allow different settings of the turn-off process.

The known concept achieves a turn-off current for n=1. In the following formula, the relationship between the period duration of the resonant circuit and the time in which the commutation can be concluded is illustrated:

$${t}_{ZOS , n} = \frac{1}{2} n {t}_{res}$$

wherein tᵣₑₛ describes the period duration of the resonance vibration and t_{ZOS,n} describes the commutation duration or the time in which the commutation can be concluded.

If, however, based on the known concept, the resonant circuit is excited with a low current, which means that a lower turn-off current is present during the switching, it is possible that the commutation time duration is increased.

By means of the inventive concept, it is possible to calculate the needed turn-off current compared to known concepts for further turn-off currents. In contrast to the known concept, in this case not only identical values of the effective capacitances are taken into consideration, but also embodiments in which these values differ from one another. FIG. 2 shows a circuit which is at least partly equivalent to FIG. 1, which includes a minimum number of needed devices. The turn-off current I_{TO,n} is modeled by an ideal current source 26. The diode D₂, 14₂ ends the commutation.

Returning to the apparatus 10 illustrated in FIG. 1, the control device 18 can be configured to set or control the turn-off current through the switching element, i.e., the current ITO,n. The control device 18 can be configured to determine the turn-off current on the basis of at least one of reading a database entry, a calculation, an analog circuit or an approximation. An analog circuit can comprise, for example, one or several transistors, operational amplifiers and/or other devices that are able to map the above-designated dependency for the turn-off current. This means that the control device can acquire knowledge of the present turn-off current indirectly or directly in order to determine when the current that is correct or at least approximated for the turn-off operation is present.

The control device 18 can be configured to set the turn-off current by means of a selection of a switching time associated with the turn-off current I_{TO,n}, in particular a switching time within a clock period.

According to an embodiment, the control device 18 can be configured to set the turn-off current through the semiconductor switch 12₁ on the basis of a reference current. This can take place, for example, by a so-called peak current mode regulation, by which the control device 18 can recognize that a correct value of the turn-off current is present.

According to an embodiment, the control device 18 can be configured to evaluate the switching operation for an occurrence of a circuit-induced overvoltage at the semiconductor switch in order to obtain an evaluation result. The evaluation result can indicate a deviation of the switching parameter from a parameter target value and the control device 18 can be configured to adapt the turn-off current through the semiconductor switch for a future switching operation in order to reduce the circuit-induced overvoltage. This means that the control device 18 can carry out a monitoring of the intended switching results and/or overvoltages. The control device 18 can then adapt the turn-off current in order to compensate for regulation errors, which can occur, for example, due to deviations, for instance when read-out database entries or other estimated values or reference values are not satisfied due to real conditions. This enables an avoidance of disadvantageous effects in the circuit.

A possibility of enabling the control device to adapt an operation can be obtained alternatively or in that the control device is configured to control the semiconductor switch 12₁ based on a reference current value, which means that when the reference current value is reached, the switching operation is triggered. Alternatively or additionally, a setting of a pulse width can be carried out, wherein the pulse width can be associated with an associated turn-off current, for instance that a larger pulse width is associated with a higher current. Alternatively or additionally, the control device can switch the semiconductor switch based on a time specification for a switching time.

A further, particularly advantageous implementation of the control device can be achieved based on the knowledge that additional low-overvoltage states are present in the circuit, for which the turn-off operations can be triggered. Thus, one of a plurality of predefined output powers can be retrievable from a correspondingly oriented circuit, for instance a DC-DC converter or another type of converter. By selecting the turn-off current, the needed output power can be retrieved and, for example, for several or even all of the adjustable needed powers, a respectively good, ideal or even optimum turn-off current can be determined or stored in a data memory accessible for the control device 18. This means that a corresponding turn-off current can be determined by the control device or can be communicated to the control device or a combination thereof.

In a further advantageous implementation of such a concept, it is likewise possible that the needed average output power or the average target output power deviates from the predefined reference values. In such a case, in which the needed target output line moves, for example, between two predefined output powers, the control device can be configured to control an operation of the apparatus based on a combination of different predefined values of the turn-off current, in order to at least approximate the target output power. A combination can be, for example, a temporal change between different operating modes, i.e. turn-off currents, and/or can relate to the determination of a mixed value. This means that for the case that the apparatus is placed into the situation that a power is needed by the apparatus for which the control device knows no inventive turn-off current, it can derive the turn-off current to be applied from values of the turn-off current of other powers, for instance by temporal change or by combination. Alternatively or additionally, however, the control device can also be configured to calculate or determine the respective optimum turn-off current and set it accordingly.

Alternatively or additionally, the apparatus can be controlled by the control device using a predefined turn-off current, wherein the control device can be configured to select that predefined turn-off current for output powers deviating from predefined average target output powers which has a smallest deviation between the obtained predefined output power and the average needed target output power. Thus, at least the negative effects obtained by possible overvoltages can be limited.

According to an embodiment, the control device is configured to provide the average target output power deviating from the different predefined output powers based on a temporal change between different predefined values of the turn-off current, for example turn-off currents, which are each associated with predefined output powers, based on a valley skipping and/or based on a burst mode. The burst mode can be advantageous when a low or very low load range is present, since it opens up the possibility of transmitting load only sporadically at all. Thus, in the case of a converter, for example, an operation down to 0% of the load can be enabled. The valley skipping can be carried out, for example, in such a way that the converter varies the power by shifting the switch-on time and thereby creating time periods without effective power transmission. This enables a power regulation by a factor of, for example, approx. 2.

If the control device is configured, for example, to provide the average target output power deviating from the different predefined average output powers, the apparatus can be controlled in a mixed operating state in order to change dynamically, for example to jump back and forth, at least between a first predefined value of the turn-off current and a second predefined value of the turn-off current. Thus, it can be achieved that, on average over time, the average target output power is obtained on average over time from the different values of the individual output powers obtained by the predefined values of the turn-off currents. The control device can be configured to adapt a clock period of the turn-off operation associated with a predefined value of the turn-off current of a predefined average output power in order to obtain a turn-off current deviating from the predefined value of the turn-off current and/or to change a target value for the turn-off current with respect to a predefined value of the turn-off current in order to change an average output current for the output power with the acceptance of increasing overvoltages. Each of these steps, the dynamic change, the adaptation of the clock period and/or the adaptation of a target value for the turn-off current can enable an adaptation of the operating state and/or enable additional operating states with respect to predefined operating states.

The control device can be configured to set the advantageous turn-off current in order to obtain intermediate circuit voltage information, wherein this can take place, for example, by prior knowledge by measurements and/or other information presentation. The intermediate circuit voltage information can indicate an intermediate circuit voltage of the commutation circuit, the voltage V_{DC}, for example encoded or as an immediate value. The control device can be configured to determine the turn-off current on the basis of the intermediate circuit voltage information. The intermediate circuit voltage can be variable or set, for example, due to different operating states of the apparatus and/or of the switch arrangement and can result in changes in the turn-off current that is taken into consideration by the control device.

According to an embodiment, the control device can be coupled to a data memory in which at least one piece of associated turn-off current information is stored for a plurality of pieces of intermediate circuit voltage information. The control device 18 can be configured to read the turn-off current information associated with the intermediate circuit voltage information and to set the turn-off current for the switching operation on the basis of the turn-off current information. This means that the control device can read out from the data memory information that indicates a level of the turn-off current to be set. For a specific value or value range of the intermediate circuit voltage information, at least one value for the turn-off current information can be present, wherein this information can relate, for example, to the current itself, a point in time or other associated information from which the control device 18 can derive and set the corresponding current according to the present invention.

The control device 18 can thus be coupled to the data memory in which, for a plurality of values of an operating parameter, such as the intermediate circuit voltage information and/or currents, voltages or the like in the apparatus, in each case at least one piece of associated turn-off current information is stored that indicates a target value for the turn-off current. The control device 18 can be configured to control or set the current through the semiconductor switch on the basis of the target value.

According to an advantageous implementation, however, it is provided that not only one value of the turn-off current information is stored but, depending on the implementation in the data memory, several pieces of turn-off current information are stored as a function of at least one further operating parameter and/or a dependency of the turn-off current information with regard to the at least second operating parameter. For example, different temperatures of the apparatus can be considered as operating parameters or different other parameters that can influence the operation of the apparatus, for example, time information that indicates an aging or other change of the operating state. The control device can be configured to read the turn-off current information associated with the operating parameter (for example, intermediate circuit voltage information) from the data memory on the basis of the first operating parameter and the at least second operating parameter and to determine the target value for the turn-off current therefrom.

According to an embodiment, the control device can completely or partly measure the needed information or completely or partly estimate or otherwise receive it, for example, via data signals. The control device can be configured, for example, to obtain measurement value information that is associated with a value of an operating state, i.e., indicates it indirectly or directly, and can be configured to calculate a target value for the turn-off current on the basis of the measurement value information. Thus, the control device can directly derive the turn-off current to be applied or set on the basis of the measurement value information.

According to an embodiment, the commutation resonant circuit described in connection with embodiments discussed herein can comprise a discrete inductive or discrete capacitive device that is connected so as to act combinatorically with a parasitic capacitance value or a parasitic inductance value of the commutation resonant circuit and to influence the resonance vibration.

For controlling or switching a semiconductor switch of a switch arrangement described herein, a gate series resistor can be used, but this is not necessary, which is why the use of a discrete resistor element can also be dispensed with. The control device can be set or configured to carry out the switching operation with a channel turn-off time duration as explained below. A performance of the driver should be configured such that the driver is able to set the channel turn-off time duration lower than the resonant frequency tres. Advantageously with a time of at most ½ tᵣₑₛ, particularly ¼ tᵣₑₛ. The lower the channel turn-off time duration, the lower the resulting overvoltage can be obtained. The switching duration is understood as the time duration in which the current in the active region of the semiconductor switch drops from 90% of the turn-off current I_{TO,n} to 10% of the turn-off current.

According to an embodiment, the semiconductor switch 12₁ is configured to be operated in a hard-switching manner in an intended operation. Alternatively or additionally, the control device is configured to hard-switch the semiconductor switch 12₁. A hard turn-off is understood as the fact that turning off takes place simultaneously at high current and high voltage.

According to an embodiment, the commutation resonant circuit is part of a commutation cell of a power electronic energy converter, for instance of a DC-DC converter, of a charger, for instance in the case of on-board chargers and/or of a brushless DC motor, BLDC motor, and/or in a lighting application such as in the case of an LED driver. This enables the advantageous application of the principle described herein in such a DC-DC converter.

According to an embodiment, an apparatus described herein, for instance the apparatus 10, is formed as a DC-DC converter that includes one of an up-converter (boost converter), a down-converter (buck converter), a half-bridge converter, a full-bridge converter, an inverting converter and a flyback converter. This enables the application of the described advantageous concept in different implementations of a DC-DC converter, wherein other implementations beyond a DC-DC converter are also possible.

Independently of the use of the control device 18 in the apparatus 10, the control device 18 can be preconfigured in such a way that it is configured to switch a semiconductor switch for carrying out a turn-off operation, for instance during a later interconnection of the semiconductor switch 12₁. The control device 18 can be configured to determine, based on a property of the semiconductor switch, that a turn-off current through the semiconductor switch satisfies the condition within a tolerance range that

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the semiconductor switch 12₁, C_{eff2} describes an effective capacitance associated with a free-running element 14₂ connected to the semiconductor switch 12₁ in the commutation circuit, Lₚ describes an effective electrical inductance of the commutation resonant circuit, and n describes a natural number; and
at least one of the conditions is satisfied:

$$n = 2 i + 1 , i ∈ ; \qquad 1 )$$

$${C}_{eff 1} \neq {C}_{eff 2} for n = 2 i + 1 , i ∈ \qquad 2 )$$

and to switch the semiconductor switch (12₁) based on the result.

This can be understood as the fact that the control device has knowledge of the turn-off current to be set and sets the turn-off current accordingly and/or selects points in time of the turn-off accordingly.

The control device can be configured to determine the property of the semiconductor switch itself, for example, by measurement, approximation or estimation, and/or to store corresponding values, for example, in a data memory. The control device can comprise an interface that is configured to obtain the corresponding information from a data memory and/or a sensor.

The control device can be configured to control the semiconductor switch on the basis of a reference current value, for example, in such a way that a switching operation takes place when the reference current value is reached. Alternatively or additionally, the control device can implement a setting of a pulse width. For this purpose, a topology and the respectively used components can also be taken into account. By varying the pulse width, a current value can be impressed by an inductance in a wide range or almost as desired. Alternatively or additionally, the control device can resort to a time specification for a switching time in order to switch the semiconductor switch based thereon.

In connection with the function for determining the optimum switching currents in the apparatus 10 and/or the control device 18, in order to determine the optimum switching currents, these can be determined according to the specified formula in dependence on the voltage, the parasitic inductance and the parasitic capacitances, optionally supplemented by discrete devices. The switching currents can thus be determined, for example, by calculating a corresponding formula or by reading off according to a table or by independently determining the optimum currents. If the optimum switching currents are known, then optionally for controlling the transistor, semiconductor switch, the regulating device or control device can set the switching current. This can take place by controlling the transistor to be turned off. The control device can achieve the optimum current, for example, by specifying a reference value, specifying a suitable pulse width and/or specifying a suitable switching time. An optional function in this case still consists in the power regulation.

Thus, applications can be present in which different powers are needed, which optionally do not result in the average current of the circuit, resulting from the turn-off current. In order to regulate the desired power, the control device can select a turn-off current that is as suitable as possible according to the relationship disclosed here. Alternatively or additionally, the control device can alternate between two or more turn-off currents I_{T0,n} in order to obtain or approximate the sought-for current on average.

A method, for example for controlling the apparatus 10, can in this respect comprise controlling the semiconductor switch for turning off and for carrying out a switching operation. The method is carried out in such a way that, for the switching operation, the semiconductor switch is switched with a channel turn-off time duration that is shorter than a period duration of a resonance vibration of the commutation circuit, in order to excite a vibration in the commutation circuit. The switching operation is carried out based on the turn-off current to be turned off, in that it is ensured within a tolerance range that

$${I}_{T 0 , n} = \frac{{V}_{DC} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current to be turned off by the semiconductor switch (12₁), V_{DC} describes an intermediate circuit voltage of the commutation circuit, C_{eff1} describes an effective capacitance of the commutation resonant circuit associated with the semiconductor switch (12₁), C_{eff2} describes an effective capacitance of the commutation resonant circuit associated with the free-running element (14₂), Lₚ describes an effective electrical inductance of the commutation resonant circuit, and n describes a natural number; and
in such a way that at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

Corresponding to the method for controlling the apparatus, a method for controlling a semiconductor switch for carrying out a turn-off operation, for instance with the aid of a control apparatus described herein, can comprise determining, based on a property of the semiconductor switch and for obtaining a result, that a turn-off current, which flows through the semiconductor switch, satisfies or has to satisfy the condition within a tolerance range that

$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$

wherein I_{T0,n} describes the turn-off current, V_{DC} describes an intermediate circuit voltage of a commutation circuit that includes the semiconductor switch, C_{eff1} describes an effective capacitance of the commutation resonant circuit associated with the semiconductor switch (12₁), C_{eff2} describes an effective capacitance associated with a free-running element (14₂) connected to the semiconductor switch (12₁) in the commutation circuit, Lₚ describes an effective electrical inductance of the commutation resonant circuit, and n describes a natural number; and
at least one of the conditions is satisfied:

$$n = 2 i + 1 , i ∈ ; \qquad 1 )$$

$${C}_{eff 1} \neq {C}_{eff 2} for n = 2 i + 1 , i ∈ . \qquad 2 )$$

It can thereby be ensured that turning-off takes place when the suitable turn-off current is present. This can take place by intervening in the turn-off operation and/or by setting the current.

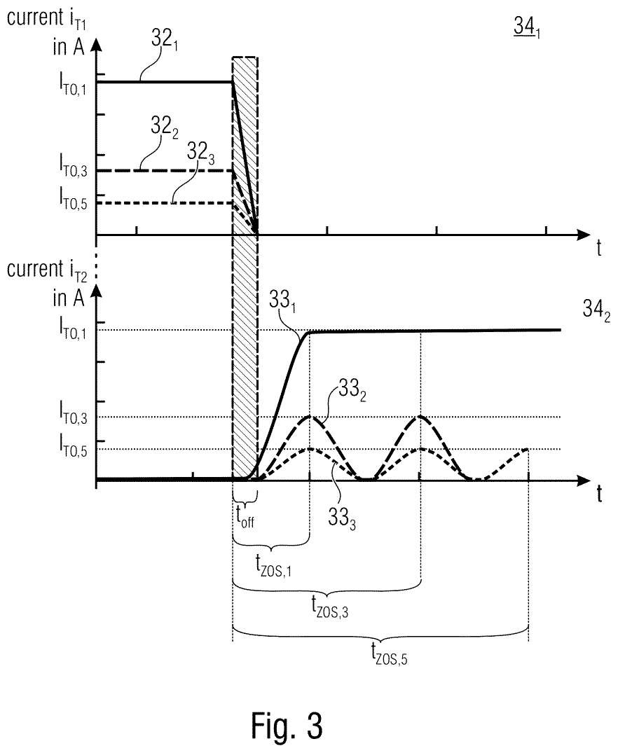

FIG. 3 shows a schematic comparison of two diagrams 34₁ and 34₂ on a common time axis t. While diagram 34₁ shows the current it through the switching element 12₁ and T₁, respectively, diagram 34₂ shows respective curves for the current i_{T2} through the switching element 12₂ and T₂, respectively. Respective schematic curves for different turn-off currents I_{TO,1}, I_{TO,3}, I_{TO,5} from the series I_{TO,n} are illustrated, wherein the amplitude of the turn-off current decreases for increasing index n. It should be noted that the index n can also have larger values, for example 7, 9, 11 or even higher.

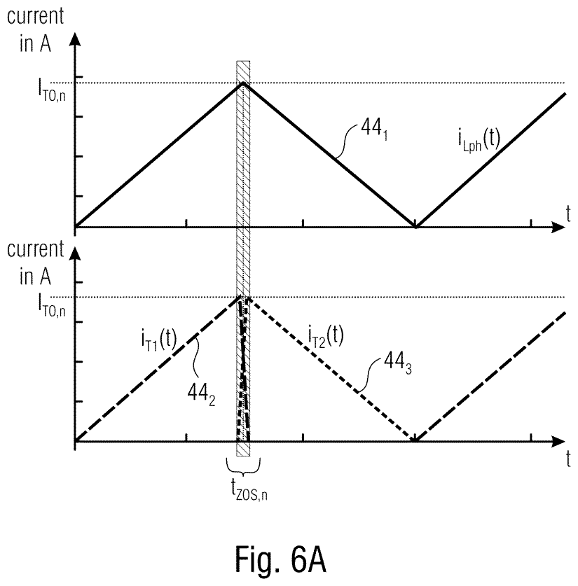

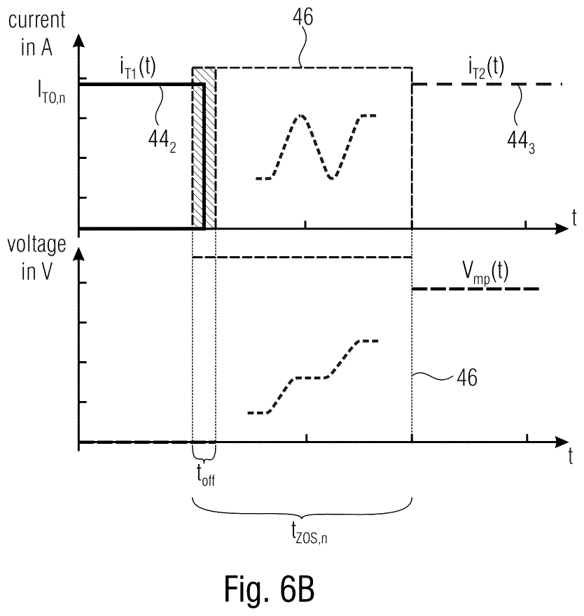

The channel turn-off time duration t_{off} is illustrated comparatively long in the schematic representation in order to enable a clear distinguishability of the curves 32₁ to 32₃ in the diagram 34₁. In fact, the channel turn-off time duration t_{off} can be very short, which in a graphical representation would result in almost overlapping and almost perpendicular curves, as is shown, for example, in FIG. 6b. With decreasing current I_{TO,n,} the associated commutation duration t_{ZOS,n} increases, as is the case with the curves 33₁ to 33₃ of the diagram 34₂.

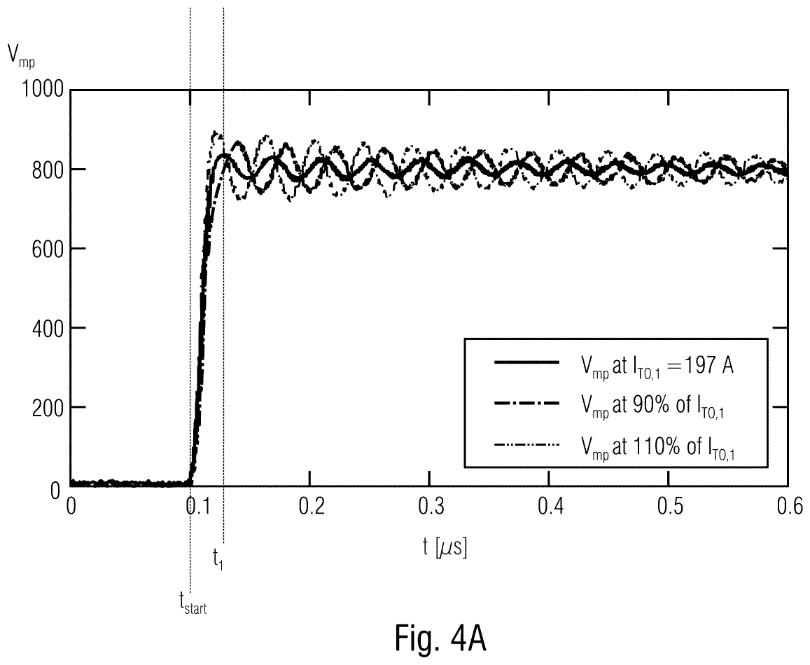

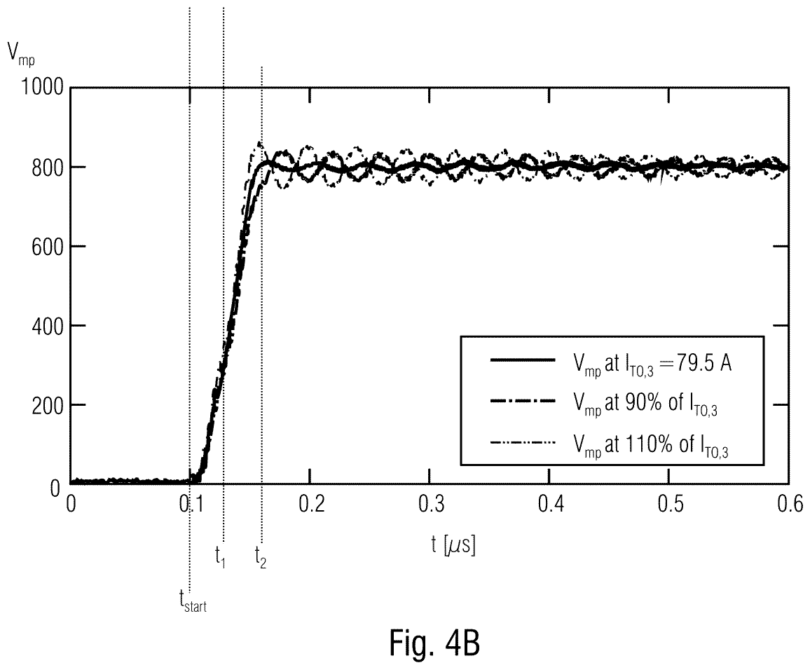

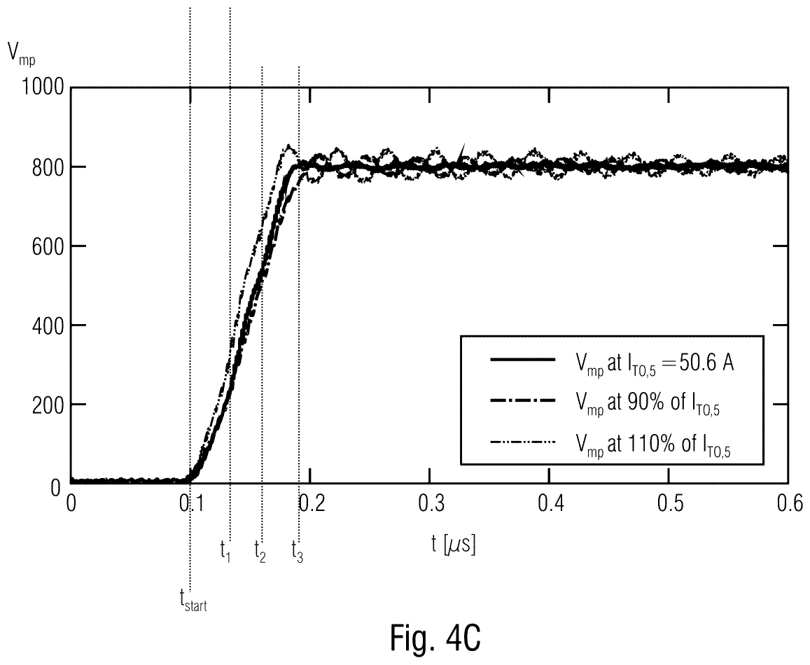

FIGS. 4a to 4c show, by way of example, voltages vmp across an exemplary semiconductor switch 12₁ of the apparatus 10 in different operating states. In this case, time specifications, current specifications and voltage specifications of the illustrated exemplary measurements are merely exemplary and not restrictive for the implementation of the embodiments described herein. Further, for the respective exemplary measurement of I_{TO,1}, I_{TO,3} and I_{TO,5}, a representation of the effect of the tolerance range of the turn-off current for deviations of, for example, +/−10% is shown.

The representations of the exemplary measurements illustrated in FIGS. 4a, 4b and 4c differ in this case in the selection of the turn-off current I_{TO,n} for n=1, n=3 and n=5, wherein the case n=1 serves as a reference and does not lie within the context of the embodiments described herein, as long as the capacitances C_{eff1} and C_{eff2} are identical, but for the case that there are differences in the capacitance values.

First, it can be seen that, starting from the point in time tₛₜₐᵣₜ for increasing n, thus decreasing turn-off currents of 197 A in FIG. 4a, 79.5 A in FIG. 4b to 50.6 A in FIG. 4c, respective later points in time t₁, t₂ and t₃ are reached until the voltage reaches an average maximum of 800 V. It is clear to the person skilled in the art that the term zero-overvoltage switching is qualitative and an actual freedom from any overshoots or oscillating overvoltages is not obtained in real operation, but that, due to the inventive implementation, the oscillating overvoltages are kept within a range, which can be regarded as interference-free for other elements of the assembly.

The fact that the selected turn-off current I_{TO,1} (FIG. 4a), I_{TO,3} (FIG. 4b) and I_{TO,5} (FIG. 4c) can be a respective optimum value is illustrated in that, for the respective curves 36₁, 36′₁ and 36″₁, respective deviations of −10% (curves 36₂, 36′₂ and 36″₂) with respect to the turn-off current or a deviation of +10% (curves 36₃, 36′₃ and 36″₃) are illustrated. From these, it can be seen that a deviation from the respective turn-off currents illustrated in the curves 36₁, 36′₁ and 36″₁ can result in an increase in the oscillating overvoltages and thus in voltage overshoots. It can be seen that, starting from the respective turn-off current, a deviation both towards higher currents and towards lower currents results in an increase in the oscillating overvoltages, wherein in particular the latter, an increase in the oscillating overvoltages in the case of switching of a lower current is surprising for the person skilled in the art.

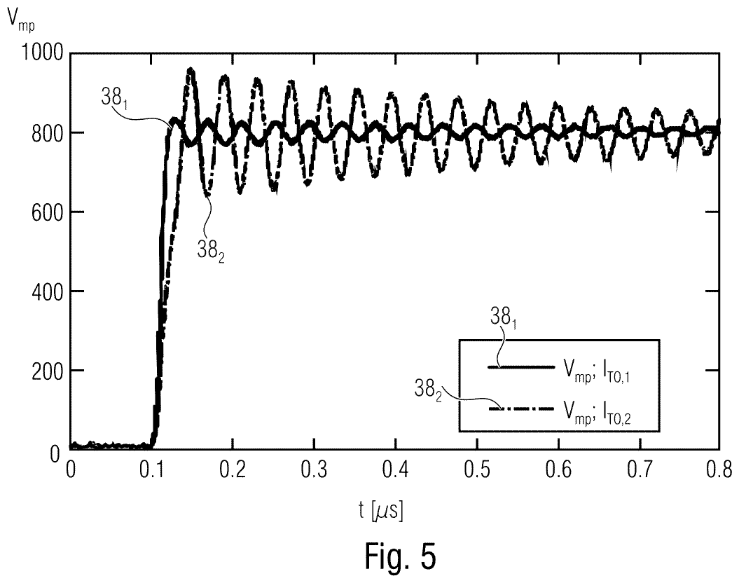

FIG. 5 shows a schematic representation of two curves 38₁ and 38₂ over time t and, at the ordinate, the voltage vₘₚ across the semiconductor switch 12₁. Here, the curve 38₂ for the value of n=2 illustrates the highest expected overvoltage below the turn-off current I_{TO,1} and explains the advantageous boundary condition of the use of odd values for the parameter n. The turn-off current at which the highest expected overvoltage occurs is achieved with I_{TO,2}.

Through the use of zero overvoltage switching (ZOS), it is possible to switch power semiconductors at maximum switching speed without the occurrence of high turn-off overvoltages. According to the invention, this effect can be set at different turn-off currents. The respective optimum turn-off currents I_{TO,n} discussed herein can be set within tolerance ranges of +/−30%, +/−20% or +/−10% in order to obtain the inventive advantages, advantageously an accuracy of +/−10%, +/−5% or +/−2% or less.

The turn-off current I_{TO}/I_{TO,n} to be set can be influenced by the intermediate circuit voltage V_{DC}, the parasitic inductance Lₚ as well as the parasitic capacitances, which are illustrated as C in the following formula.

Compared to a consideration, according to which

$${I}_{ph} = \frac{2 {U}_{Z K} \sqrt{\frac{2 C}{L}}}{π}$$

wherein U_{ZK} describes the intermediate circuit voltage, C the parasitic capacitance and L the parasitic inductance for determining the turn-off current Iₚₕ for a single ZOS point, the turn-off current is now calculated according to the invention as:

$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$

Compared to the application of ZOS at only one determined turn-off current, a higher number of turn-off currents can now be set. This also means that instead of only one current value, a higher number of current values can be used according to the present invention. This enables a high degree of freedom in the power variation of the converter system and in particular during operation in the partial load range.

According to the invention, additional advantages are thus obtained, for instance compared to a known ZOS, wherein only one turn-off current is adjustable and a partial load range would be possible, for example, only when using a valley skipping or a burst mode. Although these operating states are also compatible with the embodiments described herein, partial load operation can already be achieved by selecting different turn-off currents, which is advantageous. This also enables advantages compared to conventional converter systems of multi-phase construction, wherein individual phases are switched on or off in the partial load range. A parallelization of individual phases has the consequence that a higher component effort is needed and the costs thereby increase, which is avoided according to the invention. In these concepts for setting varying power, it is provided that the already known turn-off current is achieved in order to be able to apply the ZOS, which is avoided according to the invention by a plurality of values for the turn-off current.

According to the invention, the field of application of ZOS is extended by introducing additional turn-off currents. For this purpose, a corresponding number of turn-off currents are switched with respectively low or lowest switching losses and at least approximately without turn-off overvoltages. With further turn-off currents, it is now possible for a power electronic converter system to vary the power range with ZOS. The correct name “extended ZOS area”, eZOSa for short, describes the inventive concept that enables the power variation of the converter system to be carried out in a simple manner.

When operating power electronic energy converters in the partial load range with the use of ITO,1 only, comparatively large currents can be needed. With the inventive introduction of eZOSa, substantially lower currents can be used in order to be able to provide the needed power, in particular in the partial load range.

Embodiments advantageously enable further possible turn-off currents to be used, for instance in order to enable the setting of the needed power of an apparatus in several stages. With a certain intermediate circuit voltage, it is possible according to the invention to provide several discrete current values of a converter system. When using the further turn-off currents, the advantage of ZOS is included, which means that operation is also possible in the partial load range at maximum switching speed, with minimum resulting turn-off overvoltage. As a result, the overall efficiency of the power electronic system is increased. With a reduction of the losses, it is possible to dimension the needed cooling smaller, which can have a positive influence on weight, volume and costs.

The use of embodiments described herein as eZOSa can enable the voltage oscillations in the partial load range to be reduced, whereby the effort for filters to be applied can be reduced in order to further ensure the compliance of EMC guidelines. A lower filter effort means that the filter unit can be constructed smaller and lighter, which is advantageous.

Embodiments described herein can be used, for example, in the field of DC/DC converters, among others in the field of fuel cell applications and power electronic applications for photovoltaic and storage systems. Alternatively or additionally, applications in power electronics are possible, for example in electromobility, there among for on-board chargers and/or in the field of brushless DC motors, BLDC motors.

Alternatively or additionally, the clock period can be changed, so that a given I_{T0,n} results in different average currents. Suitable means for this are, for example, valley skipping (DCM—discontinuous current mode operation) or burst mode (turning off one or several clocks). Alternatively or additionally, the turn-off current can be changed by the value I_{T0,n} within a tolerance range of, for example, +/−20%, +/−10% or +/−5%. As a result, the device possibly deviates from the optimum ZOS turn-off current, but can change the average current to a corresponding extent, even if a low overvoltage is accepted for this purpose.

The embodiments described herein relate here both to the extended ZOS area, wherein for this purpose n>1 and/or C_{eff1}≠C_{eff2}. A control device described herein can set the turn-off current I_{T0,n}. For this purpose, the same can set the correct switching time within the clock period, for example, using a table, a calculation, an analog circuit or an approximation. Alternatively or additionally, a control device described herein can set the current through a reference current (for instance peak current regulation), for which a table, a calculation, an analog circuit or an approximation can be used.

According to embodiments, a control device is possibly adaptively configured and/or configured to evaluate the switching operation in order to possibly independently adjust the current value, for instance, as in the case of an MPP (maximum power point) tracking and/or a detection of the overvoltage by a suitable device, for instance a diode and an RC memory.

Embodiments also relate to a control device that is configured in such a way that its switching speed, current-carrying capacity and/or effective total resistance/total impedance enables the discharge of the gate and the associated turning-off of the channel of the transistor in a shorter time than the period duration of the commutation circuit. This can be referred to as defined time t_{off}, which designates the time duration of the turn-off operation of the channel of the transistor. This means that the channel turn-off time duration of the transistor can be set as low as possible, the transistor accordingly turns off as quickly as possible. The time duration of the commutation operation can vary within the eZOSa, depending on the selection of n. Depending on which n and which turn-off current is selected, different results result for this purpose. In any case, however, the selection of the channel turn-off time duration of the transistor is very low.

FIGS. 6a and 6b describe, by way of example, temporal relationships of the different parameters of embodiments described herein. Reference is made here to the block diagram of FIG. 1 and the exemplary equivalent circuit diagram of FIG. 2. FIG. 6a illustrates, on a common time axis t, on the one hand, a curve 44₁ which indicates a comparison of the current i_{Lph}(t) with respect to a determined turn-off current I_{T0,n}. Here, the turn-off current I_{T0,n} is a constant value and when this value is reached by the current I_{Lph}(t), switching of the semiconductor switch takes place in accordance with the embodiments described herein. Further, FIG. 6a shows a comparison of currents i_{T1}(t) in curve 44₂ and of the current i_{T2}(t) in curve 44₃, which alternate accordingly within the commutation duration t_{ZOS,n} due to the switching operation. The switching operation carried out when reaching the turn-off current ITO,n is advantageously carried out repeatedly. The curve 44₁ that is increasing again can be accompanied by a new, repeated switching operation when the turn-off current is reached again, as in the case of the curve 44₃.

FIG. 6b shows a temporally more detailed representation of the time interval t_{ZOS,n} of FIG. 6a, wherein, in a transition region 46, the change between an initial value and an end value of the curve 44₃ can be arbitrary and is dependent on the specific implementation of the circuit. The course of the curve 44₂ indicating the current through the semiconductor switch 12₁ can be steep, based on the set turn-off behavior.

While, at the beginning of the time interval t_{ZOS,n,} the current i_{T1}(t) in curve 44₂ at least approximately corresponds to the turn-off current, this is the case after the end of the switching operation for the curve 44₃ that indicates the current i_{T2}(t). Within the channel turn-off time duration t_{off}, the current i_{T1}(t) falls to a value associated with the disconnected state of a switch, for example 0. Within the transition region 46, FIG. 6b likewise shows the increase in the voltage vₘₚ across the switch 12₁.

Although some aspects have been described in connection with an apparatus, it is understood that these aspects also represent a description of the corresponding method, so that a block or a component of an apparatus is also to be understood as a corresponding method step or as a feature of a method step. Analogously, aspects that have been described in connection with or as a method step also represent a description of a corresponding block or detail or feature of a corresponding apparatus.

Depending on certain implementation requirements, embodiments of the invention can be implemented in hardware or in software. The implementation can take place using digital signal processing circuits such as, for example, microcontrollers, application-specific integrated circuits, ASICs, and/or in field-programmable gate arrays, FPGAs and/or using a digital storage medium.

In some embodiments, a programmable logic component such as an aforementioned FPGA can be used to carry out some or all of the functionalities of the methods described herein.

In some embodiments, a field-programmable gate array can interact with a microprocessor in order to carry out one of the methods described herein. Generally, in some embodiments, the methods are carried out on the part of any hardware apparatus. This can be universally usable hardware such as a computer processor (CPU) or hardware specific to the method, such as, for example, an ASIC.

While this invention has been described in terms of several advantageous embodiments, there are alterations, permutations, and equivalents, which fall within the scope of this invention. It should also be noted that there are many alternative ways of implementing the methods and compositions of the present invention. It is therefore intended that the following appended claims be interpreted as including all such alterations, permutations, and equivalents as fall within the true spirit and scope of the present invention.

1. Apparatus comprising:
a switch arrangement comprising a switching element that is configured for turning off an electrical current path of a commutation circuit, wherein the commutation circuit comprises a free-running element with a parallel-effective capacitance;
a control device that is configured to control the switching element for turning off and for carrying out a switching operation;
wherein the control device is configured to switch the switching element for the switching operation with a channel turn-off time duration that is shorter than a period duration of a resonance vibration of the commutation circuit, in order to excite a vibration in the commutation circuit;
wherein the control device is configured for an operating state, in which the switching operation is carried out based on a turn-off current to be turned off, if it is satisfied within a tolerance range that:
$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$
wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number;
wherein at least one of the conditions is satisfied:
$$n = 2 i + 1 , i ∈ ; \qquad 1 )$$
$${C}_{eff 1} \neq {C}_{eff 2} for n = 2 i + 1 , i ∈ . \qquad 2 )$$

2. Apparatus according to claim 1, wherein the condition is satisfied that
$$n = 2 i + 1 , i ∈ .$$

3. Apparatus according to claim 1, wherein the condition is satisfied that
$${C}_{eff 1} \neq {C}_{eff 2} . \qquad 2 )$$

4. Apparatus according to claim 1, wherein the control device is configured to set the turn-off current through the switching element.

5. Apparatus according to claim 4, wherein the control device is configured to determine the turn-off current on the basis of at least one of reading a database entry, a calculation, an analog circuit or an approximation.

6. Apparatus according to claim 4, wherein the control device is configured to set the turn-off current by means of a selection of a switching time associated with the turn-off current.

7. Apparatus according to claim 4, wherein the control device is configured to set the turn-off current through the switching element on the basis of a reference current.

8. Apparatus according to claim 4, wherein the control device is configured to evaluate the switching operation for an occurrence of a circuit-induced overvoltage at the switching element to acquire an evaluation result which indicates a deviation of the switching parameter from a parameter target value; wherein the control device is configured to adapt the turn-off current through the switching element for a future switching operation in order to reduce the circuit-induced overvoltage.

9. Apparatus according to claim 1, wherein the control device is configured to control the switching element based on a reference current value, a setting of a pulse width, or based on a time specification for a switching time.

10. Apparatus according to claim 1, which is configured to provide a respective predefined average output power in different operating states, wherein a predefined value of the turn-off current is associated with each of the predefined average output powers;
wherein the control device is configured to control an operation of the apparatus based on a combination of different predefined values of the turn-off current in order to at least approximate the target output power to set an average target output power which deviates from the different predefined output powers; or
to control the apparatus using a predefined turn-off current that comprises a smallest deviation between the acquired predefined output power and the average target output power.

11. Apparatus according to claim 10, wherein the control device is configured to provide the average target output power deviating from the different predefined output powers on the basis of at least one of
a temporal change between different predefined values of the turn-off current;
a valley skipping; and
a burst mode.

12. Apparatus according to claim 10, which is configured to control the apparatus in a mixed operating state to provide the average target output power deviating from the different predefined average output powers to change dynamically at least between a first predefined value of the turn-off current and a second predefined value of the turn-off current to acquire the average target output power on average over time;
to adapt a clock period of the turn-off operation associated with a predefined value of the turn-off current of a predefined average output power to acquire a turn-off current deviating from the predefined value of the turn-off current; and/or
to change a target value for the turn-off current with respect to a predefined value of the turn-off current to change an average output current for the output power with the acceptance of increasing overvoltages.

13. Apparatus according to claim 1, wherein the control device is configured to acquire intermediate circuit voltage information that indicates an intermediate circuit voltage of the commutation circuit, wherein the control device is configured to determine the turn-off current on the basis of the intermediate circuit voltage information.

14. Apparatus according to claim 13, wherein the control device is coupled to a data memory in which, for a plurality of pieces of intermediate circuit voltage information, at least one piece of associated turn-off current information is stored, wherein the control device is configured to read the turn-off current information associated with the intermediate circuit voltage information and to set the turn-off current for the switching operation on the basis of the turn-off current information.

15. Apparatus according to claim 1, wherein the control device is coupled to a data memory in which, for a plurality of values of an operating parameter, at least one piece of associated turn-off current information each is stored that indicates a target value for the turn-off current, wherein the control device is configured to control the current through the switching element on the basis of the target value.

16. Apparatus according to claim 15, wherein the operating parameter is a first operating parameter and the respectively associated turn-off current information is a first piece of turn-off current information that is associated with a first value of a second operating parameter; wherein, in the data memory, second turn-off current information are stored for the plurality of values of the first operating parameter that are associated with a second value of the second operating parameter, wherein the control device is configured to read the turn-off current information associated with the first operating parameter from the data memory on the basis of the first operating parameter and the second operating parameter and to determine the target value for the turn-off current therefrom.

17. Apparatus according to claim 1, wherein the control device is configured to acquire measurement value information that is associated with a value of an operating state, and wherein the control device is configured to calculate a target value for the turn-off current on the basis of the measurement value information.

18. Apparatus according to claim 1, wherein the commutation resonant circuit comprises a discrete inductive or discrete capacitive device that is connected so as to act combinatorically with a parasitic capacitance value or a parasitic inductance value of the commutation resonant circuit and that influences the resonance vibration.

19. Apparatus according to claim 1, wherein the switching element is configured to be operated in a hard-switching manner in an intended operation; and/or wherein the control device is configured to hard-switch the switching element.

20. Apparatus according to claim 1, wherein the commutation resonant circuit is part of a commutation cell of a power electronic energy converter.

21. Apparatus according to claim 1, which is formed as a DC-DC converter that comprises one of an up-converter, a down-converter, a half-bridge converter, a full-bridge converter, an inverting converter and a flyback converter.

22. Control device that is configured to switch a switching element for carrying out a turn-off operation, comprising:
wherein the control device is configured to determine, based on a property of the switching element, a result that indicates a turn-off current that flows through the switching element for the turn-off operation, that satisfies the condition within a tolerance range that:
$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$
wherein I_{T0,n} describes the turn-off current, V_{DC} describes an intermediate circuit voltage of a commutation circuit that comprises the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and
at least one of the conditions is satisfied:
$$n = 2 i + 1 , i ∈ ; \qquad 1 )$$
$${C}_{eff 1} \neq {C}_{eff 2} for n = 2 i + 1 , i ∈ \qquad 2 )$$
and to switch the switching element based on the result.

23. Control device according to claim 22, wherein the interface is configured to acquire the information from a data memory and/or a sensor.

24. Control device according to claim 22, wherein the control device is configured to control the semiconductor switch based on a reference current value, a setting of a pulse width, or based on a time specification for a switching time.

25. Method for controlling an apparatus with a switch arrangement comprising a switching element that is configured for turning off an electrical current path of a commutation circuit, wherein the commutation circuit comprises a free-running element with a parallel-effective capacitance; comprising:
controlling the switching element for turning off and for carrying out a switching operation;
so that, for the switching operation, the switching element is switched with a channel turn-off time duration that is shorter than a period duration of a resonance vibration of the commutation circuit, in order to excite a vibration in the commutation circuit;
so that the switching operation is carried out based on the turn-off current to be turned off, if it is satisfied within a tolerance range that:
$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$
wherein I_{T0,n} describes the turn-off current to be turned off by the switching element, V_{DC} describes an intermediate circuit voltage of the commutation circuit, C_{eff1} describes an effective capacitance of the commutation resonant circuit associated with the switching element, C_{eff2} describes an effective capacitance of the commutation resonant circuit associated with the free-running element, Lₚ describes an effective electrical inductance of the commutation resonant circuit, and n describes a natural number; and
so that at least one of the conditions is satisfied:
$$n = 2 i + 1 , i ∈ ; \qquad 1 )$$
$${C}_{eff 1} \neq {C}_{eff 2} for n = 2 i + 1 , i ∈ . \qquad 2 )$$

26. Method for controlling a switching element for carrying out a turn-off operation, comprising:
determining, based on a property of the switching element and for acquiring a result that indicates a turn-off current that flows through the switching element for the turn-off operation, that satisfies the condition within a tolerance range that:
$${I}_{T 0 , n} = \frac{{V}_{D C} \sqrt{\frac{{( {C}_{eff 1} + {C}_{eff 2} )}^{3}}{{C}_{eff 1} {C}_{eff 2} {L}_{p}}}}{n π}$$
wherein I_{T0,n} describes the turn-off current, V_{DC} describes an intermediate circuit voltage of a commutation circuit that comprises the semiconductor switch, C_{eff1} describes an effective capacitance of the commutation resonant circuit associated with the switching element, C_{eff2} describes an effective capacitance associated with a free-running element connected to the switching element in the commutation circuit, Lₚ describes an effective electrical inductance of the commutation resonant circuit, and n describes a natural number; and
at least one of the conditions is satisfied:
$$n = 2 i + 1 , i ∈ ; \qquad 1 )$$
$${C}_{eff 1} \neq {C}_{eff 2} for n = 2 i + 1 , i ∈ . \qquad 2 )$$
